(19) United States
(12) Patent Application Publication
(10) Pub. No.: US 2019/0006197 A1
(43) Pub. Date: Jan. 3, 2019

(54) WAFER PART AND CHIP PACKAGING METHOD

(71) Applicants: BOE TECHNOLOGY GROUP CO., LTD., Beijing (CN); BEIJING BOE DISPLAY TECHNOLOGY CO., LTD., Beijing (CN)

(72) Inventors: Yuanxin Du, Beijing (CN); Zhidong Wang, Beijing (CN); Lianjie Qu, Beijing (CN); Yonglian Qi, Beijing (CN); Yun Qiu, Beijing (CN); Zhenhua Lv, Beijing (CN)

(21) Appl. No.: 15/991,374

(22) Filed: May 29, 2018

(30) Foreign Application Priority Data
Jul. 3, 2017 (CN) 201710536380.4

(51) Int. Cl. H01L 21/56; H01L 23/31; H01L 21/02; H01L 23/544; H01L 29/06; H01L 21/78

(52) U.S. Cl. CPC H01L 21/561; H01L 23/31; H01L 21/02021; H01L 21/67092; H01L 29/0657; H01L 21/78; H01L 23/544

(57) ABSTRACT

A wafer part and a chip packaging method are provided. The wafer part is obtained by processing a round wafer. A profile of the wafer part is an inscribed closed pattern of a profile of the round wafer, and area of the inscribed closed pattern is larger than area of an inscribed square of the profile of the round wafer; the inscribed closed pattern includes an even number of straight edges, and each one of straight edges is parallel to another of the straight edges and has a length equal to that of the another of the straight edges. The chip packaging method includes: fixing the plurality of wafer parts on a first panel level substrate and forming a packaging structure on each chip; wherein the plurality of wafer parts are arranged closely on the first panel level substrate without being overlapped with each other.

### CROSS-REFERENCE TO RELATED APPLICATION

This application claims the benefit of Chinese Patent Application No. 201710536380.4 filed on Jul. 3, 2017 in the State Intellectual Property Office of China, the whole disclosure of which is incorporated herein by reference.

### FIELD OF THE DISCLOSURE

The present disclosure relates to the field of semiconductor technology, and in particular to wafer part and a chip packaging method.

### DESCRIPTION OF THE RELATED ART

With the continuous development of integrated circuit (IC) technology, gradually decreased size of IC wafers, and continuously improved degree of integration, ever-increasing demands are placed on the packaging of integrated circuits. Processes for chip packaging in the related art of the semiconductor industry mainly includes: cutting a round wafer, so as to divide the round wafer into individual chips, re-arranging the qualified chips on the substrate in a regular manner, and then performing packaging, forming re-distribution layers (referred to as RDLs) and performing a process to solder balls.

### SUMMARY

The embodiments of the present disclosure provide a wafer part which is obtained by processing a round wafer, a profile of the wafer part being an inscribed closed pattern of a profile of the round wafer, wherein area of the inscribed closed pattern is larger than area of an inscribed square of the profile of the round wafer; and wherein the inscribed closed pattern comprises an even number of straight edges, and each one of straight edges is parallel to another of the straight edges and has a length equal to that of the another of the straight edges.

In an embodiment of the present disclosure, the profile of the wafer part is an inscribed polygon of the profile of the round wafer.

In an embodiment of the present disclosure, the profile of the wafer part is an inscribed regular hexagon of the profile of the round wafer.

In an embodiment of the present disclosure, the profile of the wafer part is an inscribed octagon of the profile of the round wafer.

In an embodiment of the present disclosure, the inscribed closed pattern further comprises an arced corner between two adjacent straight edges, and the arced corner is arc segment of the profile of the round wafer.

In an embodiment of the present disclosure, the inscribed closed pattern is a closed pattern with four straight edges and four arced corners, the four straight edges having equal lengths, and the four arced corners having equal arcs.

The embodiments of the present disclosure further provide a chip packaging method, comprising: fixing a plurality of wafer parts mentioned above on a first panel level substrate and forming a packaging structure on each chip; wherein the plurality of wafer parts are arranged closely on the first panel level substrate without being overlapped with each other.

In an embodiment of the present disclosure, the packaging structure comprises re-distribution layers; and wherein the chip packaging method further comprises: after forming a packaging structure on each chip, cutting the wafer part into individual chips and the re-distribution layers connected to the chips, and then re-arranging the chips and the re-distribution layers connected to the chips on the second panel level substrate, encapsulating the chips to form a packaging layer.

In an embodiment of the present disclosure, the packaging structure comprises a post and a solder cap; the chip packaging method further comprises: after forming a packaging structure on each chip, cutting the wafer part into individual chips as well as the post and the solder cap electrically connected to the chips, encapsulating the chips to form a packaging layer after the solder cap is connected to re-distribution layers.

The embodiments of the present disclosure further provide a chip packaging method, comprising: fixing a plurality of wafer parts mentioned above on a first panel level substrate and forming a packaging structure on each chip; wherein the plurality of wafer parts are arranged closely on the first panel level substrate without being overlapped with each other.

In an embodiment of the present disclosure, the packaging structure comprises re-distribution layers; the chip packaging method further comprises: after forming a packaging structure on each chip, cutting the wafer part into individual chips and the re-distribution layers connected to the chips, and then re-arranging the chips and the re-distribution layers connected to the chips on the second panel level substrate, encapsulating the chips to form a packaging layer.

In an embodiment of the present disclosure, the packaging structure comprises a post and a solder cap; the chip packaging method further comprises: after forming a packaging structure on each chip, cutting the wafer part into individual chips as well as the post and the solder cap electrically connected to the chips, encapsulating the chips to form a packaging layer after the solder cap is connected to re-distribution layers.

### BRIEF DESCRIPTION OF THE DRAWINGS

In order to more clearly illustrate solutions of the embodiments of the present disclosure or those in the prior art, a briefly description to the drawings for explaining the embodiments or the prior art is provided below. Obviously, the drawings in the following description are only some embodiments of the present disclosure, which do not form any limitation to the present disclosure.

FIG. 1 is a schematic view of a profile of a wafer part provided by the present disclosure;

FIG. 2 is a schematic view of another profile of a wafer part provided by the present disclosure;

FIG. 3 is a schematic view of yet another profile of a wafer part provided by the present disclosure;

FIG. 4 is a schematic view of yet another profile of a wafer part provided by the present disclosure;

FIG. 5 is a schematic view of yet another profile of a wafer part provided by the present disclosure;

FIG. 6 is a schematic view of a round wafer and the round wafer has a plurality of chips;

FIG. 7 is a schematic view of a plurality of wafer parts according to the present disclosure shown in FIG. 1 being arranged on the first panel level substrate;

FIG. 8 is a schematic view of a plurality of wafer parts according to the present disclosure shown in FIG. 2 being arranged on the first panel level substrate;

FIG. 9 is a schematic view of a plurality of wafer parts according to the present disclosure shown in FIG. 3 being arranged on the first panel level substrate;

FIG. 10 is a schematic view of a plurality of wafer parts according to the present disclosure shown in FIG. 4 being arranged on the first panel level substrate;

FIG. 11 is a schematic view of a plurality of wafer parts according to the present disclosure shown in FIG. 5 being arranged on the first panel level substrate;

FIG. 12 is a schematic view of a plurality of wafer parts according to the present disclosure shown in FIG. 6 being arranged on the first panel level substrate;

FIG. 13a is a schematic view of re-distribution layers formed on chips of a wafer part provided by the present disclosure;

FIG. 13b is a schematic view of the wafer part of FIG. 13a cut to form individual chips and re-distribution layers connected to the chips;

FIG. 14a is a schematic view of a post and a solder cap formed on chips of the wafer parts provided by the present disclosure;

FIG. 14b is a schematic view of the wafer part of FIG. 14a cut to form individual chips as well as a post and a solder cap connected to the chips;

FIG. 15a is a flow chart of the method provided by an embodiment of the present disclosure; and

FIG. 15b is a flow chart of the method provided by another embodiment of the present disclosure.

### DETAILED DESCRIPTION OF PREFERRED EMBODIMENTS

The following clearly describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without any creative efforts shall fall within the protection scope of the present disclosure.

According to a general inventive concept of the present disclosure, there is provided a wafer part which is obtained by processing a round wafer, a profile of the wafer part being an inscribed closed pattern of a profile of the round wafer, wherein area of the inscribed closed pattern is larger than area of an inscribed square of the profile of the round wafer; and wherein the inscribed closed pattern includes an even number of straight edges, and each one of the straight edges is parallel to another of the straight edges and has a length equal to that of the another of the straight edges.

The embodiments of the present disclosure provide a wafer part and a chip packaging method. The wafer part is obtained by processing a round wafer so as to form a profile which is an inscribed closed pattern of the profile of the round wafer. By providing that area of the inscribed closed pattern is larger than area of the inscribed square of the profile of the round wafer, a utilization rate of the round wafer will not be too low (may reach up to 63% or more). By providing that the inscribed closed pattern includes an even number of straight and each one of the straight edges is parallel to another of the straight edges and has a length equal to that of the another of the straight edges, it may be ensured that, when the wafer parts are arranged on the first panel level substrate, a utilization rate of the first panel level substrate is higher than the utilization rate of the first panel level substrate when the round wafers are arranged on the first panel level substrate. In summary, the utilization rate of round wafers and that of panel level substrates are compatible in the present disclosure, thereby saving costs. In addition, by fixing the wafer parts onto the first panel level substrate, a process for forming a packaging structure may be performed in the production line of the panel field, so that the production scale and production efficiency may be improved, and the cost of the packaging in the related art may be saved.

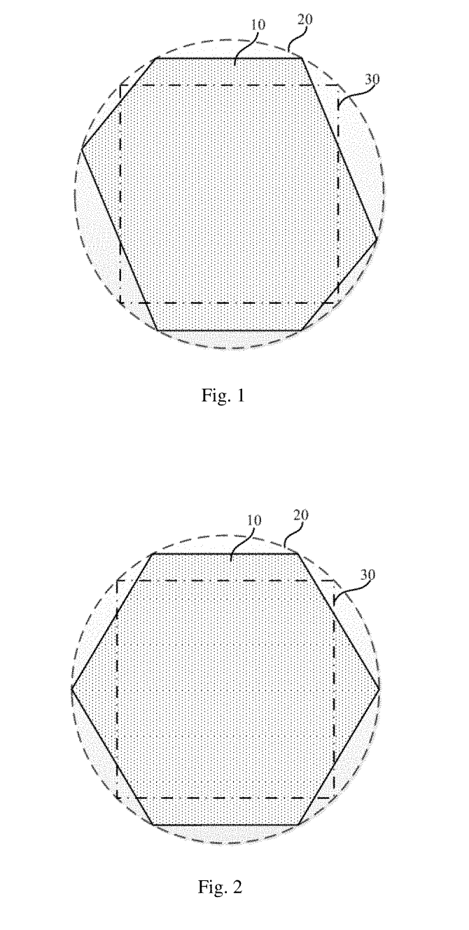

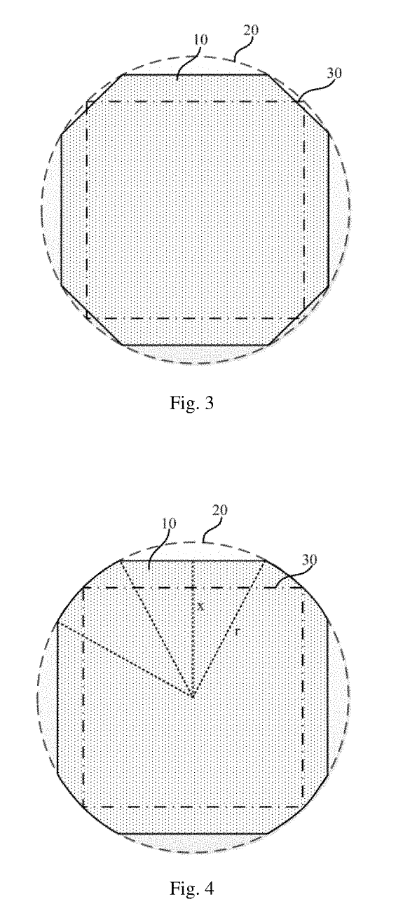

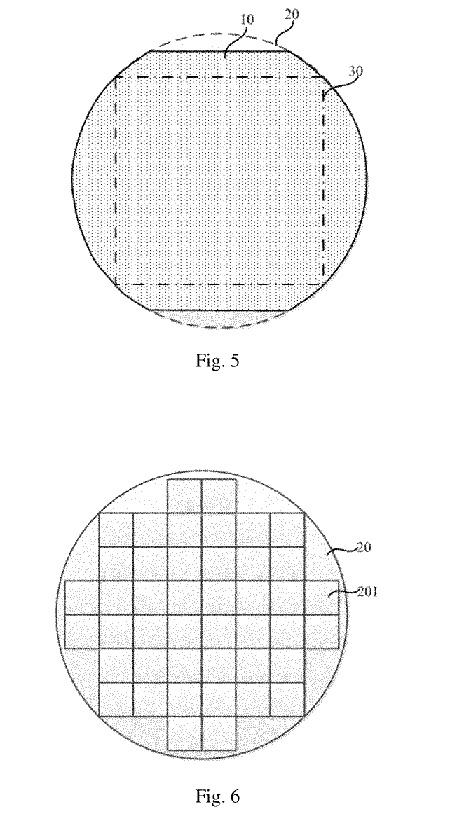

The embodiment of the present disclosure provides a wafer part 10, as shown in FIGS. 1-5, obtained by processing a round wafer 20. The wafer part 10 includes a plurality of chips. The profile of the wafer part 10 is an inscribed closed pattern of the profile of the round wafer 20. The area of the inscribed closed pattern is larger than the area of an inscribed square 30 of the profile of the round wafer 20; the inscribed closed pattern includes an even number of straight edges, and each one of the straight edges is parallel to another of the straight edges and has a length equal to that of the another of the straight edges.

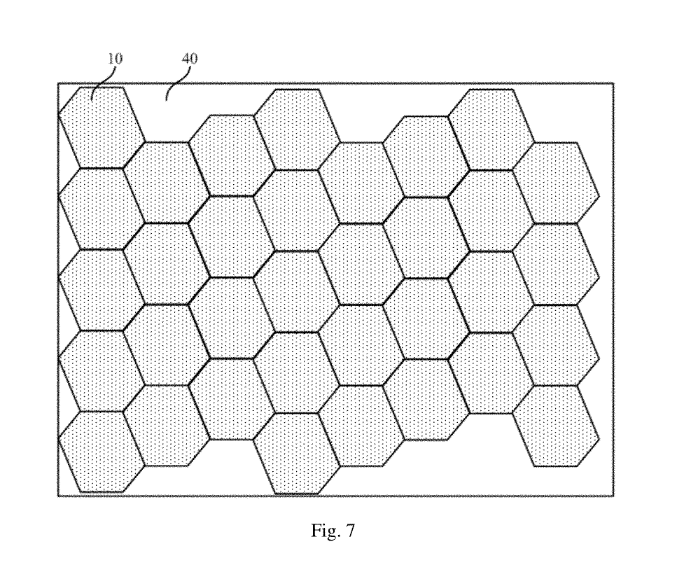

It should be noted that the profile of the round wafer 20 is a circle as shown in FIGS. 1 and 6, and its diameter may be 6 inches, 8 inches, 12 inches, and the like.

Each one of the round wafers 20 includes a plurality of chips 201.

In addition, the round wafer 20 is processed into the wafer part 10 without changing thickness thereof.

Since the area of the wafer part 10 is smaller than the area of the round wafer 20, when the round wafer 20 is processed into the wafer part 10, those chips 201 located on the round wafer 20 except for a region where the wafer part 10 is located will be cut off so as to obtain a wafer part 10 with a desired profile.

In addition, when the round wafer 20 is processed into its inscribed square 30, assuming that the radius of the round wafer 20 is r, and the utilization rate of the round wafer 20 may only reach up to 2r²/r²=63%. In the embodiment of the present disclosure, the area of the wafer part 10 is larger than the area of the inscribed square 30, so the utilization rate of the round wafer 20 of the present disclosure is greater than 63%, thereby reducing waste of the chips 201.

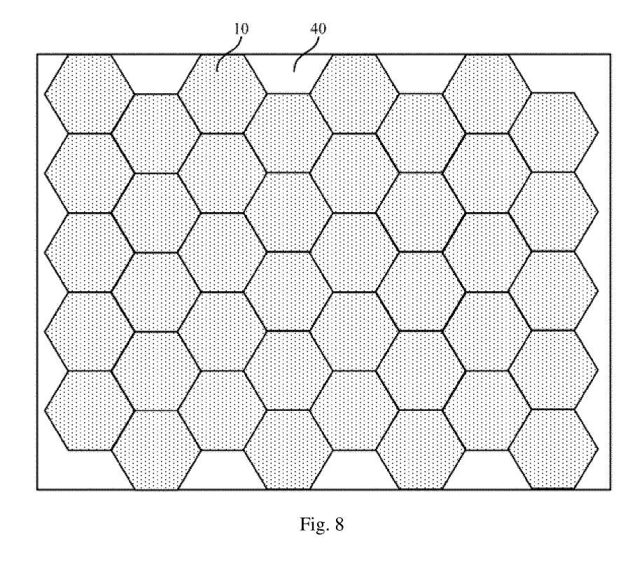

In addition, when the profile of the wafer part 10 is of hexagon, and each one of straight edges of the hexagon is parallel to another of the straight edges and has a length equal to that of the another of the straight edges, especially when the profile of the wafer part 10 is a regular hexagon, as shown in FIGS. 7 and 8, the wafer parts 10 of the present disclosure are arranged on the first panel level substrate 40 closely without being overlapped with each other, there is no gaps between any adjacent ones of the wafer parts 10 without considering the edges of the first panel level substrate 40. Therefore the utilization rate of the first panel level substrate 40 is high.

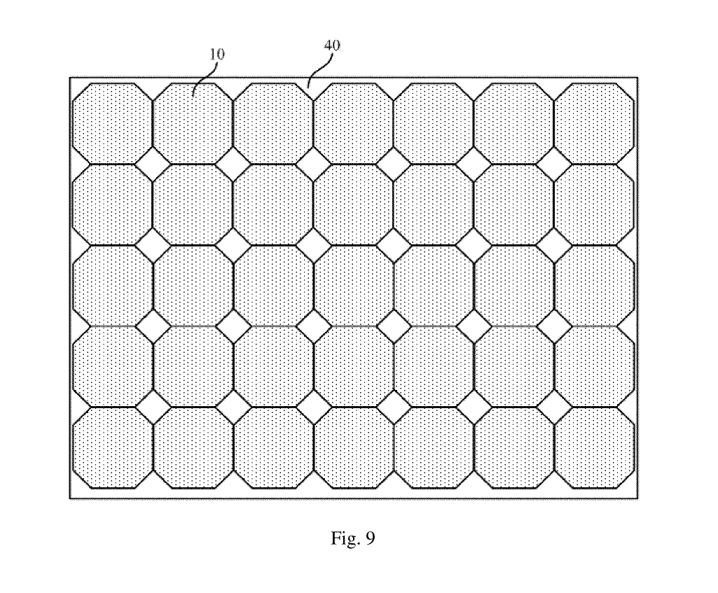

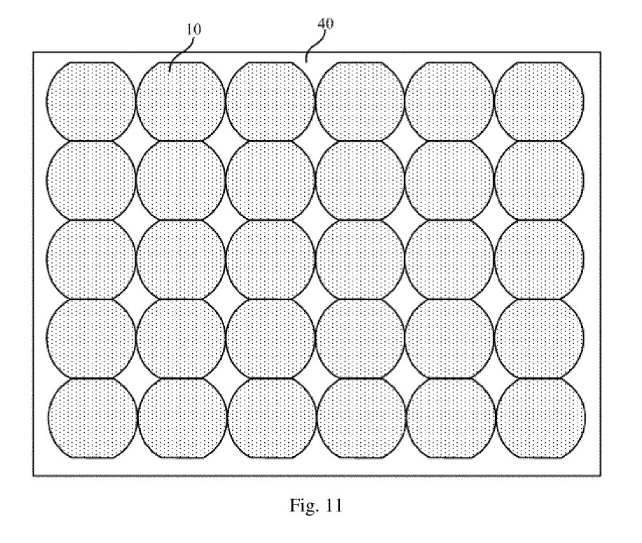

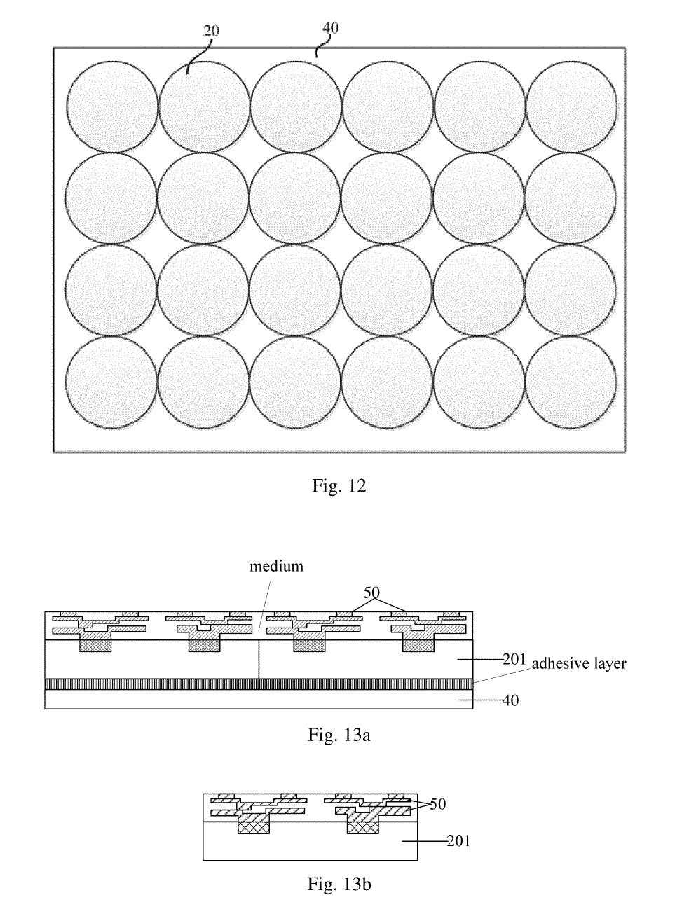

When the profile of the wafer part 10 is a polygon having a number of straight edges, and the number is greater than six and is an even number, and each one of straight edges of the polygon is parallel to another of the straight edges and has a length equal to that of the another of the straight edges, especially when the profile of the wafer part 10 is the octagon for example as shown in FIG. 9, the wafer parts 10 of the present disclosure are arranged on the first panel level substrate 40 closely without being overlapped with each other. Without considering the edges of the first panel level substrate 40, there will be a gap surrounded by any adjacent four wafer parts 10. However, compared to the gaps surrounded by any adjacent four round wafers 20 as shown in FIG. 12 (the wafer part 10 in FIG. 9 is obtained through the round wafer 20), the gap surrounded by any adjacent four wafer parts 10 in FIG. 9 is smaller, and thus the utilization rate of the first panel level substrate 40 is also higher.

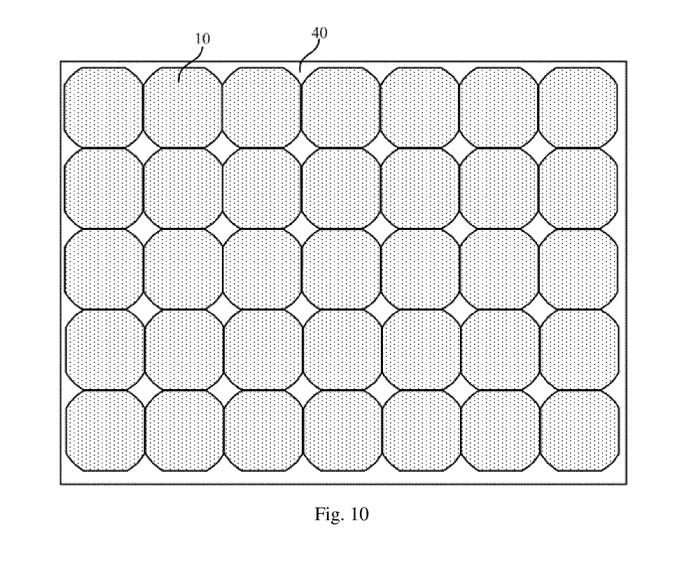

In an embodiment, the profile of the wafer part 10 is a polygon having a number of straight edges, and the number is four or more and is an even number, and each one of straight edges of the polygon is parallel to another of the straight edges and has a length equal to that of the another of the straight edges, and further an arced corner is located between two adjacent straight edges. Four straight edges in FIG. 10 are taken as an example. As shown in FIG. 10, the wafer parts 10 of the present disclosure are arranged on the first panel level substrate 40 closely without being overlapped with each other. Without considering the edges of the first panel level substrate 40, there will also be a gap surrounded by any adjacent four wafer parts 10. However, compared to the gaps surrounded by any adjacent four round wafers 20 as shown in FIG. 12 (the wafer part 10 in FIG. 10 is obtained through the round wafer 20), the gap surrounded by any adjacent four wafer parts 10 in FIG. 10 is smaller, and thus the utilization rate of the first panel level substrate 40 is also higher.

When the profile of the wafer part 10 includes two opposite straight edges which are disposed in parallel and have equal lengths, and further includes two opposite arc edges, as shown in FIG. 11, the wafer parts 10 of the present disclosure are arranged on the first panel level substrate 40 closely without being overlapped with each other. Without considering the edges of the first panel level substrate 40, there will be a gap surrounded by any adjacent four wafer parts 10. However, compared to the gaps surrounded by any adjacent four round wafers 20 as shown in FIG. 12 (the wafer part 10 in FIG. 11 is obtained through the round wafer 20), the gap surrounded by any adjacent four wafer parts 10 in FIG. 11 is smaller, and thus the utilization rate of the first panel level substrate 40 is also higher.

Regardless of the wafer parts 10 of the present disclosure having any profiles, when the wafer parts 10 being arranged on the first panel level substrate 40, there will be gaps at the edges of the first panel level substrate 40. However, the larger the size of the first panel level substrate 40 is, the smaller the proportion of gaps at the edge of the first panel level substrate 40 to the area of the first panel level substrate 40 is correspondingly. Of course, when the round wafers 20 being arranged on the first panel level substrate 40, there are also gaps at the edges of the first panel level substrate 40.

In addition, the profile of the wafer parts 10 in FIGS. 1-5 is only schematic, comprehensively considering the cost of the chips 201 and the cost of the first panel level substrate 40, the utilization rate of the round wafer 20 and the utilization rate of the first panel level substrate 40 may be set for the purpose of minimizing the total cost, and the wafer part 10 with a suitable profile is selected accordingly.

The embodiments of the present disclosure provide a wafer part 10. The wafer part 10 is obtained by processing a round wafer 20 so as to form a profile which is an inscribed closed pattern of the profile of the round wafer. By providing that area of the inscribed closed pattern is larger than area of the inscribed square of the profile of the round wafer 20, a utilization rate of the round wafer 20 will be relatively high (may reach up to 63% or more). By providing that the inscribed closed pattern includes an even number of straight edges and each one of straight edges is parallel to another of the straight edges and has a length equal to that of the another of the straight edges, it may be ensured that, when the wafer parts 10 are arranged on the first panel level substrate 40, a utilization rate of the first panel level substrate 40 is higher than the utilization rate of the first panel level substrate 40 when the round wafers 20 are arranged on the first panel level substrate 40. In summary, the utilization rate of round wafers 20 and that of panel level substrates are compatible in the present disclosure, thereby saving costs.

For example, as shown in FIGS. 1-3, the profile of the wafer part 10 is an inscribed polygon of the profile of the round wafer 20.

By processing the profile of the wafer part 10 into an inscribed polygon, the utilization rate of the first panel level substrate 40 may be further improved on the basis of ensuring the utilization rate of the round wafer 20.

Further alternatively, as shown in FIG. 2, the profile of the wafer part 10 is an inscribed regular hexagon of the profile of the round wafer 20.

Herein, assuming the radius of the round wafer 20 is r, and the area of an inscribed regular hexagon of the profile of the round wafer 20 is

$$\frac{1}{2} \times r \times \sqrt{{r}^{2} - \frac{1}{4} {r}^{2}} \times 6 = \frac{3 \sqrt{3}}{2} {r}^{2} .$$

Based on this, the utilization rate of the round wafer 20 may reach up to

$$\frac{3 \sqrt{3}}{2} {r}^{2} / π {r}^{2} \approx 87 \% .$$

In addition, when the wafer parts 10 are arranged closely on the first panel level substrate 40 (as shown in FIG. 8) without being overlapped with each other, the utilization rate of the first panel level substrate 40 may reach up to 100% in case that the edges of the first panel level substrate 40 are not taken in consideration.

The embodiment of the present disclosure may achieve maximization of the utilization rate of the round wafer 20 and maximization of the utilization rate of the first panel level substrate 40 by processing the profile of the wafer part 10 into an inscribed regular hexagon of the profile of the round wafer 20.

For example, as shown in FIG. 4, the inscribed closed pattern further includes an arced corner located between two adjacent straight edges, and the arced corner is obtained from an arc segment of the profile of the round wafer 20.

That is, as shown in FIG. 4, when the round wafer 20 is processed into the wafer part 10, it is only needed to cut off the portion of the round wafer 20 outside the straight edges denoted by those solid lines in FIG. 4 to form the wafer part 10 with the arced corners.

In the embodiments of the present disclosure, the process of machining a round wafer 20 into a wafer part 10 are simpler.

Further alternatively, as shown in FIG. 4, the inscribed closed pattern is a closed pattern with four edges of an equal length and four corners of an equal arc degree.

Assuming that the radius of the round wafer 20 is r, and a distance from the center of the circle to respective straight edge is x, under such a condition, the area of the inscribed closed pattern of the profile of the round wafer 20 is:

$$\frac{π {r}^{2}}{360 °} ( 90 ° - 2 arccos \frac{x}{r} ) \times 4 + 4 x \sqrt{{r}^{2} - {x}^{2}}$$

Based on this, the utilization rate of round wafer 20=

$$\frac{\frac{π {r}^{2}}{360 °} ( 90 ° - 2 arccos \frac{x}{r} ) \times 4 + 4 x \sqrt{{r}^{2} - {x}^{2}}}{π {r}^{2}} .$$

When the wafer parts 10 are arranged closely on the first panel level substrate 40 without being overlapped with each other (as shown in FIG. 10), the utilization rate of the first panel level substrate 40 is equal to

$$\frac{\frac{π {r}^{2}}{360 °} ( 90 ° - 2 arccos \frac{x}{r} ) \times 4 + 4 x \sqrt{{r}^{2} - {x}^{2}}}{4 {x}^{2}} .$$

As for the value of x, a reasonable choice may be made according to the desired utilization rate of the round wafer 20 and the desired utilization rate of the first panel level substrate 40.

In the embodiment of the present disclosure, the profile of the wafer part 10 is processed into a closed pattern with four straight edges of an equal length and four corners with an equal arc degree, which is more conducive to improving the utilization rate of the round wafer 20. At the same time, although the utilization rate of the first panel level substrate 40 cannot reach up to 100%, the utilization rate of the first panel level substrate 40 is also high.

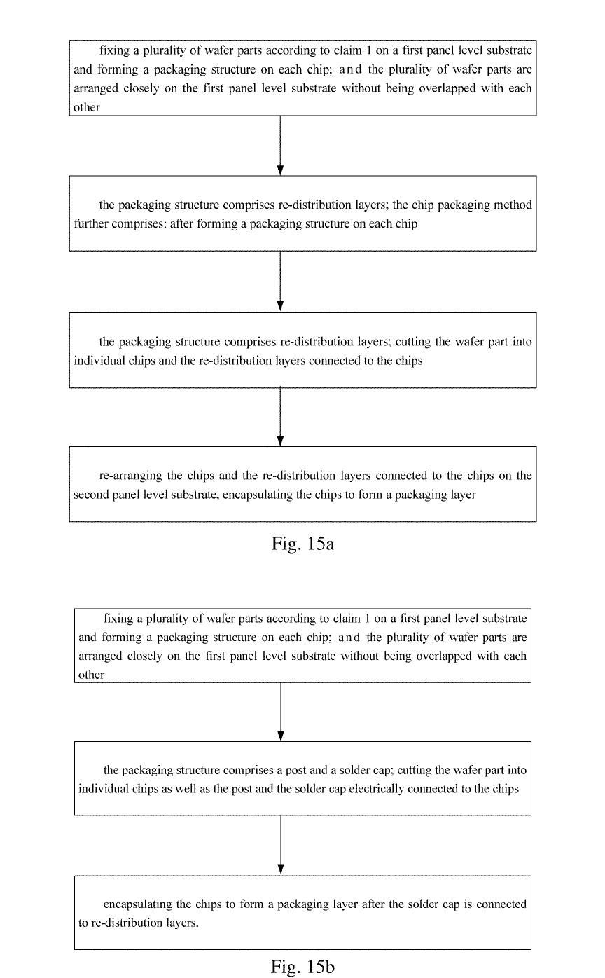

The embodiments of the present disclosure further provide a chip packaging method. As shown in FIGS. 7-11 and 15a-b, the method includes arranging a plurality of above-mentioned wafer parts 10 closely without being overlapped with each other and fixing them on the first panel level substrate 40, and then forming a packaging structure on each one of the chips 201.

The first panel level substrate 40 is a substrate used in the panel industry, for example, a substrate of 1100 mm×1300 mm, 2200 mm×2500 mm and the like.

The wafer parts 10 may be fixed onto the first panel level substrate 40 through an adhesive layer. The material of the adhesive layer may be, for example, a double-sided tape or a UV adhesive or the like.

It should be noted that, when forming the packaging layer, there should be a gap between the chips 201. Therefore, before forming the packaging layer, the wafer parts 10 should be fixed onto the first panel level substrate 40 so as to form a packaging structure with a large area simultaneously. The wafer parts are then cut to form individual chips.

In the embodiments of the present disclosure, by fixing the wafer parts 10 onto the first panel level substrate 40, a process for forming a packaging structure may be performed in the production line of the panel field, so that the production scale and production efficiency may be improved, and the cost of the packaging in the related art may be saved.

For example, as shown in FIG. 13a, the packaging structure includes re-distribution layers (RDLs) 50; based on this, the chip packaging method further includes: after forming a packaging structure on each chip 201, cutting the wafer part into individual chips 201 and the re-distribution layers 50 connected to the chips 201 (as shown in FIG. 13b), and then re-arranging the chips 201 and the re-distribution layers 50 connected to the chips 201 on the second panel level substrate, packaging the chips 201 to form an packaging layer. Of course, the re-distribution layers 50 connected to each chip 201 are also divided by cutting the medium around the re-distribution layers 50 such that the re-distribution layers 50 connected to different chips 201 are separated from each other.

The size of the second panel level substrate and that of the first panel level substrate 40 are for example the same.

When each wafer part 10 includes N chips 201 and M wafer parts 10 are disposed on the first panel level substrate 40, M×N individual chips 201 may be obtained after cutting; where M and N are positive integer.

After M×N individual chips 201 are obtained by cutting, each chip 201 may be tested, the qualified chips 201 may be selected to be re-arranged on the second panel level substrate, and then the packaging layer for protecting chips 201 may be formed.

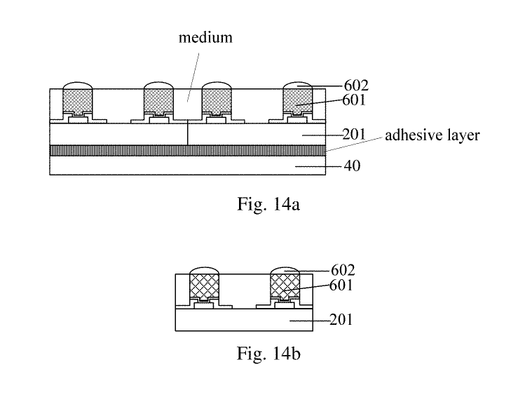

For example, as shown in FIG. 14a, the packaging structure includes a post 601 and a solder cap 602; and based on this, the chip packaging method further includes: after forming a packaging structure on each chip 201, forming individual chips 201 as well as the post 601 and the solder cap 602 electrically connected to the chip 201 (as shown in FIG. 14b) by a cutting process, encapsulating the chips 201 to form a packaging layer after the solder cap 602 is connected to the re-distribution layers.

The re-distribution layers of each chip 201 have been already formed on the second panel level substrate in advance, and in order to ensure that a packaging layer is formed around each chip 201, there should be a space between the re-distribution layers connected to respective chips 201.

The foregoing descriptions are merely specific implementation manners of the present disclosure, but the protection scope of the present disclosure is not limited thereto. Those modifications or replacements which may be easily conceived within the technical scope disclosed by the present disclosure by any person skilled in the art should be included within the scope of the disclosure. Therefore, the protection scope of the present disclosure should be defined on basis of the protection scope of the claims.

What is claimed is:

1. A wafer part which is obtained by processing a round wafer, a profile of the wafer part being an inscribed closed pattern of a profile of the round wafer, wherein area of the inscribed closed pattern is larger than area of an inscribed square of the profile of the round wafer; and wherein
the inscribed closed pattern comprises an even number of straight edges, and each one of straight edges is parallel to another of the straight edges and has a length equal to that of the another of the straight edges.

2. The wafer part according to claim 1,
wherein the profile of the wafer part is an inscribed polygon of the profile of the round wafer.

3. The wafer part according to claim 2,
wherein the profile of the wafer part is an inscribed regular hexagon of the profile of the round wafer.

4. The wafer part according to claim 2,
wherein the profile of the wafer part is an inscribed octagon of the profile of the round wafer.

5. The wafer part according to claim 1,
wherein the inscribed closed pattern further comprises an arced corner between two adjacent straight edges, and the arced corner is arc segment of the profile of the round wafer.

6. The wafer part according to claim 5,
wherein the inscribed closed pattern is a closed pattern with four straight edges and four arced corners, the four straight edges having equal lengths, and the four arced corners having equal arcs.

7. A chip packaging method, comprising: fixing a plurality of wafer parts according to claim 1 on a first panel level substrate and forming a packaging structure on each chip;
wherein the plurality of wafer parts are arranged on the first panel level substrate without being overlapped with each other.

8. The method according to claim 7, wherein the packaging structure comprises re-distribution layers; and wherein
the chip packaging method further comprises: after forming a packaging structure on each chip,
cutting the wafer part into individual chips and the re-distribution layers connected to the chips, and then re-arranging the chips and the re-distribution layers connected to the chips on the second panel level substrate, encapsulating the chips to form a packaging layer.

9. The method according to claim 7, wherein the packaging structure comprises a post and a solder cap;
the chip packaging method further comprises: after forming a packaging structure on each chip, cutting the wafer part into individual chips as well as the post and the solder cap electrically connected to the chips, encapsulating the chips to form a packaging layer after the solder cap is connected to re-distribution layers.

10. A chip packaging method, comprising: fixing a plurality of wafer parts according to claim 3 on a first panel level substrate and forming a packaging structure on each chip;
wherein the plurality of wafer parts are arranged on the first panel level substrate without being overlapped with each other.

11. The chip packaging method according to claim 10, wherein the packaging structure comprises re-distribution layers;
the chip packaging method further comprises: after forming a packaging structure on each chip,
cutting the wafer part into individual chips and the re-distribution layers connected to the chips, and then re-arranging the chips and the re-distribution layers connected to the chips on the second panel level substrate, encapsulating the chips to form a packaging layer.

12. The chip packaging method according to claim 10, wherein the packaging structure comprises a post and a solder cap;
the chip packaging method further comprises: after forming a packaging structure on each chip, cutting the wafer part into individual chips as well as the post and the solder cap electrically connected to the chips, encapsulating the chips to form a packaging layer after the solder cap is connected to re-distribution layers.
